(19) United States
(12) Patent Application Publication
(10) Pub. No.: US 2025/0079274 A1
(43) Pub. Date: Mar. 6, 2025

(54) POWER MODULE

(71) Applicants: Hyundai Motor Company, Seoul (KR); Kia Corporation, Seoul (KR)

(72) Inventors: Han Jin DO, Incheon (KR); Jin Myeong YANG, Seongnam-si (KR); Sung Won PARK, Incheon (KR)

(21) Appl. No.: 18/611,180

(22) Filed: Mar. 20, 2024

(30) Foreign Application Priority Data
Sep. 4, 2023 (KR) 10-2023-0117080

(51) Int. Cl. H01L 23/498; H01L 23/00; H01L 23/31; H01L 23/373

(52) U.S. Cl. CPC H01L 23/49811; H01L 23/3735; H01L 23/49833; H01L 23/3121; H01L 24/32; H01L 24/33; H01L 2224/32225; H01L 2224/33181

(57) ABSTRACT

A power module includes a first substrate including a plurality of layers that are stacked in a first direction and extend in a second direction crossing the first direction, a semiconductor chip connected to the first substrate in the first direction, and a first lead that extends in the first direction, the first lead having a first end electrically connected to the first substrate and a second end exposed to an outside of the power module.

### CROSS REFERENCE TO RELATED APPLICATION

The present application claims priority to Korean Patent Application No. 10-2023-0117080, filed on Sep. 4, 2023, the entire contents of which are incorporated herein for all purposes by this reference.

### TECHNICAL FIELD

The present disclosure relates to a power module having a structure to increase the current superposition effect.

### BACKGROUND

With the growing interest in the environment, there is a trend of increasing eco-friendly vehicles equipped with electric motors as power sources. Eco-friendly vehicles, also known as electrified vehicles, include electric vehicles (EVs) and hybrid electric vehicles (HEVs).

In electrified vehicles, an inverter may be equipped to convert direct current power to alternating current power for motor operation, and the inverter is usually composed of one or multiple power modules incorporating semiconductor chips that perform switching functions.

In some examples, as the output requirements for inverters continue to rise, the heat generation of semiconductor chips is also increasing to support high output, leading to an increase in the size of key components such as semiconductor chips and substrates to handle the increased heat.

However, there is a need to address reliability issues, such as the degradation of the module's electrical characteristics or the occurrence of substrate warping, which can occur as the module size increases and the current loops become longer and more complex.

The description of the background technology provided above is intended to enhance understanding of the background of the present disclosure and should not be construed as an acknowledgment that it is known prior art to those skilled in this technical field.

### SUMMARY

It is an object of the present disclosure to provide a power module capable of increasing the current superposition effect and enhancing electrical characteristics by reducing the current loop through the shape and structure of leads connected to external terminals.

The objects of the present disclosure are not limited to the aforesaid, and other objects not described herein will be clearly understood by those skilled in the art from the descriptions below.

In order to accomplish the above objects, a power module includes a first substrate formed by stacking a plurality of layers and extended in a direction crossing the direction of the stacking, a semiconductor chip connected to the first substrate in the direction of the stacking, and a first lead member electrically connected at one end to the first substrate and extended in the direction of the stacking to be exposed at the other end to the outside.

For example, the other end of the first lead member may be connected to an external terminal.

For example, a power module may further include a molding member covering at least part of the first substrate, the semiconductor chip, and part of the first lead member, wherein the other end of the first lead member may include an exposed surface exposed to the outside of the molding member.

For example, the other end of the first lead member may extend to a level corresponding to an outer surface of the outermost layer among the plurality of layers of the first substrate.

For example, the first lead member may be connected at one end to the first substrate and extended from the one end in the direction of extension of the first substrate and bent and extended at the other end in the direction of the stacking.

For example, the plurality of layers may include an insulating layer and a metal layer arranged on a surface of the insulating layer, the surface facing the semiconductor chip, and the one end of the first lead is connected to the metal layer.

For example, a power module may further include a second substrate spaced apart from the first substrate in the direction of the stacking, with the semiconductor chip positioned therebetween, and a second lead member electrically connected at one end to the second substrate and extended at the other end in the direction of the stacking to be exposed to the outside.

For example, the other ends of the first and second lead members may be connected to different external terminals.

For example, the different external terminals may correspond to the P terminal and N terminal, respectively.

For example, the other ends of the first and second lead members may be aligned on one side relative to the semiconductor chip in the direction of extension of the first substrate.

For example, the other ends of the first and second lead members may overlap at least partially in the planar view in the direction of the stacking.

For example, a power module may further include a third lead member extended in the direction of extension of the first substrate, connected at one end to at least one of the first and second substrates, and exposed at the other end to the outside in the direction of extension of the first substrate.

For example, the other end of the third lead member may protrude in the direction of extension of the first substrate to be exposed to the outside.

For example, the first and third lead members may be connected to different external terminals.

For example, the third lead member may be aligned on the opposite side relative to the first lead member with respect to the semiconductor chip in the direction of extension of the first substrate.

As described above, the power module in various implementations of the present disclosure is advantageous in terms of implementing a compact current loop through the lead structure allowing the external terminals connected to the power module to be arranged in a short vertical direction rather than a wide horizontal direction.

This allows for an enhancement in the performance of the power module by mitigating or shortening the extension of the current path even when component sizes are enlarged for high power and heat dissipation purposes.

The advantages of the present disclosure are not limited to the aforesaid, and other advantages not described herein may be clearly understood by those skilled in the art from the descriptions below.

### BRIEF DESCRIPTION OF THE DRAWINGS

FIG. 1 is a cross-sectional view illustrating an example configuration of a power module.

FIG. 2 is a perspective view illustrating an example appearance of the power module of FIG. 1 as seen from the outside.

FIGS. 3A to 5D are diagrams illustrating example shapes and arrangements of first, second, and third lead members.

### DETAILED DESCRIPTION

The specific structural or functional descriptions of the implementations of the disclosure disclosed in this specification or patent application are illustrative examples intended to describe implementations of the present disclosure, and the implementations of the present disclosure can be implemented in various forms and should not be construed as being limited to those described in this specification or the application.

In some implementations, a power module may be designed with a pad-shaped portion for connection to external terminals, which allows performance improvement based on the electrical characteristics of the power module through increased current superposition effect with the formation of relatively narrow current loop even when the size is increased.

In some examples, the first substrate 110 and the second substrate 120 are distinguished in the following description for the convenience of explanation but are not restricted solely to their arrangement or structure as depicted in the drawings.

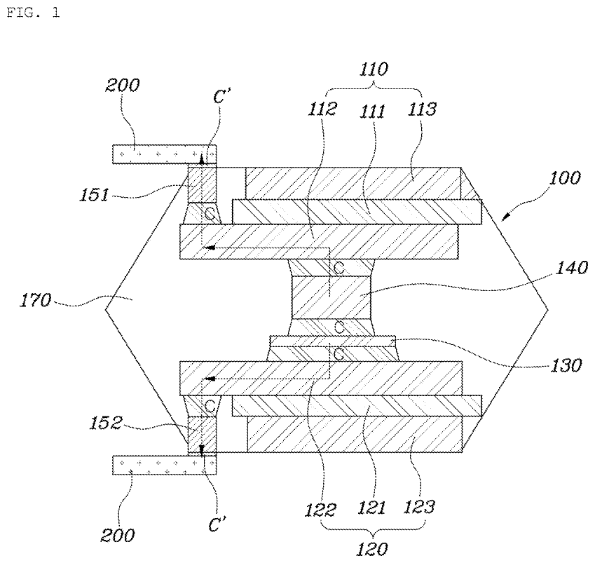

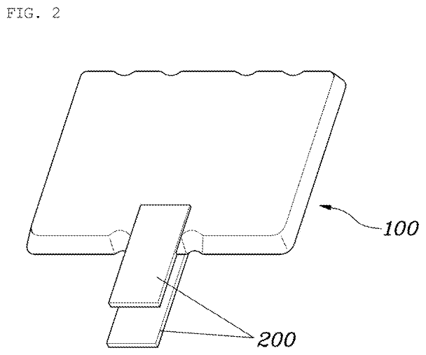

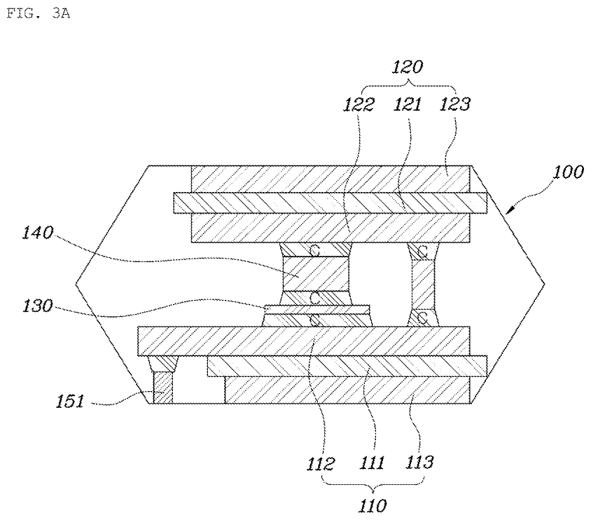

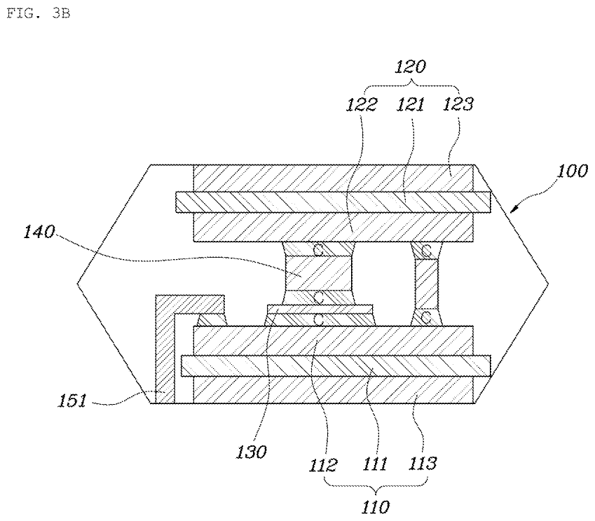

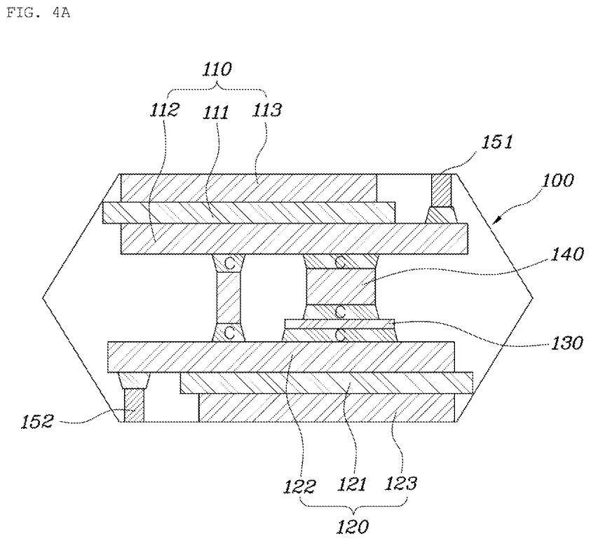

Hereinafter, a description is made of the overall configuration of the power module 100 with reference to FIGS. 1 to 2.

FIG. 1 is a cross-sectional view illustrating a configuration of a power module, and FIG. 2 is a perspective view illustrating the appearance of the power module of FIG. 1 as seen from the outside.

With reference to FIG. 1, in some implementations, the power module 100 may include a first substrate 110, a second substrate 120, a semiconductor chip 130, a spacer 140, a first lead member 151 (“first lead”), a second lead member 152 (“second lead”), a third lead member 153 (“third lead”), and a molding member 170 (“molding”). However, it should be noted that FIG. 1 only shows the components essential to the description of an implementation of the present disclosure, and the actual power module 100 may be implemented with more or fewer components.

In some implementations, the first substrate 110 may be formed by stacking a plurality of layers 111, 112, and 113, which may extend in directions crossing the direction of the stacking. That is, the first substrate 110, in shape, consists of a plurality of layers stacked in the vertical direction and extended in the horizontal direction on the drawing.

The semiconductor chip 130 may be connected to the first substrate 110 in the direction of stacking the plurality of layers 111, 112, and 113. In more detail, the semiconductor chip 130 may be attached to the first substrate 110 through an adhesive material C or connected to the first substrate 110 via a spacer 140, and FIG. 1 shows the appearance of the semiconductor chip 130 being connected to the first substrate 110 via a spacer 140. In some examples, the semiconductor chip 130 may be connected to the first substrate 110 through soldering or sintering, and the adhesive material C may be implemented using various materials with conductivity.

The first lead member 151 may be electrically connected at one end to the first substrate 110 and exposed at the other end outward in the direction of stacking the plurality of layers 111, 112, and 113.

In this case, the other end of the first lead member 151 may be connected to an external terminal 200.

Particularly, the other end of the first lead member 151 exposed outward in the direction of stacking the plurality of layers 111, 112, and 113 may have an exposed surface. That is, the exposed end of the first lead member 151 may be implemented in the form of a pad, and in this case, the exposed surface of the other end of the first lead member 151 and the external terminal 200 may be bonded face to face. The other end of the first lead member 151 and the external terminal 200 may be connected directly or via an adhesive material C′ or the like. In this case, the adhesive material C′ may be made of various materials with conductivity.

In some examples, the other end of the first lead member 151 may be formed by extending in the direction in which the plurality of layers 111, 112, and 113 constituting the first lead member 151 is stacked. In more detail, the other end of the first lead member 151 may extend to a level corresponding to the outer surface of the outermost layer among the plurality of layers 111, 112, and 113 of the first substrate 110. For example, in the direction of stacking the plurality of layers 111, 112, and 113 of the first substrate 110, the other end of the first lead member 151 may extend up to or short of the level of the outer surface of the outermost layer among the plurality of layers 111, 112, and 113 of the first substrate 110.

In this case, the power module 100 has a structure in which a portion of the first lead member 151 is exposed to the outside for connection to external terminals 200, while ensuring that some parts of the current path are not directly exposed to the outside, allowing for insulation to be maintained and protecting internal components.

With the exclusion of the other end, the first lead member 151 may be covered by the molding member 170 preventing exposure to the outside, and thus only the exposed surface formed on the other end of the first lead member 151 may be exposed to the outside of the molding member 170.

The molding member 170 may cover not only a portion including the one end of the first lead member 151 but also at least a portion of the internal components of the power module 100, such as the semiconductor chip 130, the spacer 140, and the first substrate 110, thereby blocking electrical connections with the outside.

In some examples, the plurality of layers 111, 112, and 113 constituting the first substrate 110 may include an insulating layer 111, a metal layer 112 arranged on a surface of the insulating layer, the surface facing the semiconductor chip 130, and a metal layer 113 arranged on the opposite surface of the insulating layer 111.

Here, the insulating layer 111 may, for example, be made of ceramics, the metal layers 112 and 113 may, for example, be made of copper (Cu), and the first substrate 110 may be implemented as an active metal brazed substrate (AMB) or a direct bonded copper (DBC) substrate.

In this case, one end of the first lead member 151 may be connected to the metal layer 112 among the first substrate 110. The metal layer 112 is electrically connected to the semiconductor chip 130, allowing the first lead member 151 to form a part of the current loop by being connected to the metal layer 112.

In more detail, one end of the first lead member 151 may be connected to the metal layer 112 on the surface facing or opposite the semiconductor chip 130 or a side of the metal layer 112, and for this purpose, the plurality of layers 111, 112, and 113 of the first substrate 110 may be implemented with varying lengths, as shown in FIG. 1. In addition, as long as one end of the first lead member 151 can be electrically connected to the first substrate 110, the detailed connection structure may be flexibly implemented in various manners.

In some examples, the power module 100 may include, in addition to the first substrate 110, a second substrate 120 spaced apart from the first substrate 110 in the direction in which the plurality of layers 111, 112, and 113 of the first substrate 110 are stacked, with the semiconductor chip 130 positioned therebetween.

That is, the power module 100 may be implemented with a dual-sided cooling method where heat generated by the semiconductor chip 130 is dissipated through both the substrates 110 and 120.

The second substrate 120 may also be composed of a plurality of layers 121, 122, and 123 stacked and extending in the direction crossing the direction of the stacking in a similar manner as the first substrate. Additionally, the second substrate 120 is electrically connected to the semiconductor chip 130, and, for example, as shown in FIG. 1, when the first substrate 110 is connected to one side of the semiconductor chip 130 via a spacer 140, the second substrate 120 may be connected to the other side of the semiconductor chip 130.

The first substrate 110 and the second substrate 120 may be referred to as the upper and lower substrates but are not necessarily limited to either the upper substrate or the lower substrate. For example, in some implementations, it may also be conceivable to the implementation of the power module 100 in which the arrangement of the first substrate 110 and the second substrate 120 is reversed.

In some examples, in the power module 100 including the first and second substrate 110 and substrates 120, the lead member may be connected to the side of the first substrate 110 only but the lead member may also be connected to the side of the second substrate 120.

In more detail, the power module 100 may further include a second lead member 152, one end of which is electrically connected to the second substrate 120 and the other end is exposed to the outside in direction of the stacking of either the first substrate 110 or the second substrate 120.

Here, the first lead member 151 and the second lead member 152 are distinguished for convenience of explanation, and in the power module 100 including a plurality of lead members, the lead member connected to the first substrate 110 may be referred to as the first lead member (151) while the lead member connected to the second substrate 120 may be referred to as the second lead member 152.

When lead members are connected to both the first substrate 110 and the second substrate 120, the other ends of the first lead member 151 and the second lead member 152 may be connected to different external terminals 200. In this case, the different external terminals 200 may correspond to P and N terminals, respectively.

Particularly, the other ends of the first lead member 151 and the second lead member 152 may be aligned on one side relative to the semiconductor chip 130 in the direction of extension of the first substrate 110 or the second substrate 120. For example, the other ends of both the first lead member 151 and the second lead member 152 may be aligned to the left, as shown in FIG. 1.

Furthermore, the other ends of the first lead member 151 and the second lead member 152 may overlap at least partially in the planar view in direction of the stacking of either the first substrate 110 or the second substrate 120.

In this case, external terminals 200 respectively connected to the first lead member 151 and the second lead member 152 may also overlap in the planar view, being aligned on one side, as shown in FIG. 2, which allows the current loop of the power module 100 to be formed more narrowly in the vertical direction rather than widely in the horizontal direction. By forming the current loop in a narrow vertical configuration, the current superposition effect is enhanced, leading to improved performance based on the electrical characteristics of the power module 100.

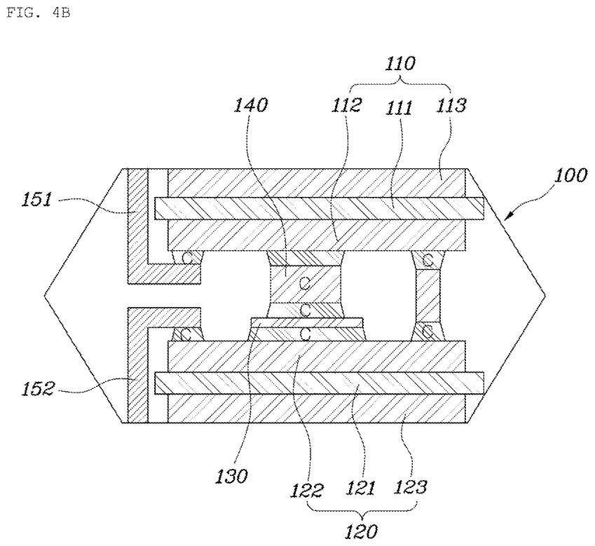

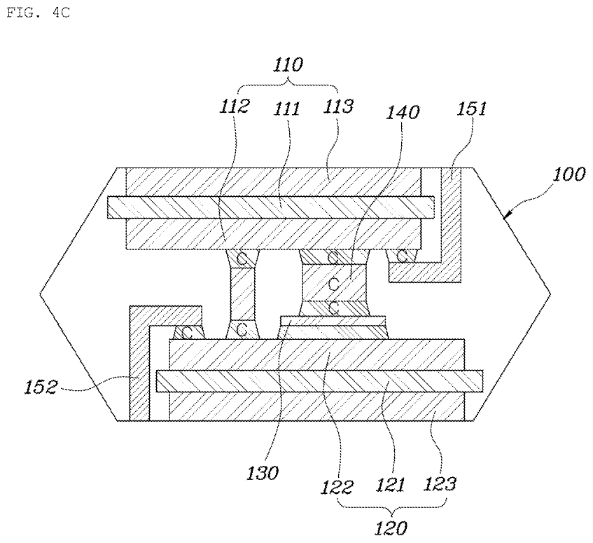

Hereinafter, descriptions are made of the internal structures applicable to the above-described power module 100 according to various implementations with reference to FIGS. 3A to 4D.

FIGS. 3A to 4D are diagrams illustrating the shapes and arrangements of first, second, and third lead members according to implementations of the present disclosure.

In some implementations, FIGS. 3A and 3B show the power module 100 with a dual-sided cooling structure using the first and second substrates 110 and 120, with the lead member connected to only one of the substrates.

In this case, unlike in FIG. 1, the substrate located at the lower part of the drawing may be referred to as the first substrate 110, and the lead member connected to the substrate may be referred to as the first lead member 151.

The first lead member 151 may have a structure in which one end is connected to the metal layer 112 of the first substrate 110 and the other end is exposed to the outside, extending in direction of the stacking of the first substrate 110, as shown in FIG. 3A. That is, in an implementation, the first lead member 151 may be implemented to have a straight shape without any bent portions in cross-section.

In contrast, with reference to FIG. 3B, the first lead member 151 may be connected at one end to the first substrate 110 and extended from the one end in the direction of extension of the first substrate 110 and bent and extended at the other end in direction of the stacking of the plurality of layers 111, 112, and 113. That is, the first lead member 151 may have a structure in which the other end extended in direction of the stacking of the first substrate 110 as shown in FIG. 3A and the one end extended in the direction of extension (i.e., horizontal direction on the drawing) other than direction of the stacking of the first substrate 110 are connected via a bent portion therebetween.

Despite the difference in detailed shapes between FIGS. 3A and 3B, the structure of the first lead member 151 involves one end being connected to the first substrate 110 and the other end being exposed to the outside, and various other shapes may be applied to the first lead member 151 to ensure that one end is connected to the first substrate 110 and the other end is exposed to the outside.

In some examples, although the description has been focused on the first lead member 151 in FIGS. 3A and 3B, the second lead member 152 may also be implemented in a similar manner to the first lead member 151.

In some implementations, FIGS. 4A to 4C show the power module 100 with a dual-sided cooling structure using the first and second substrates 110 and 120, similar to FIG. 1, with the lead members connected to both the substrates.

With reference to FIG. 4A, the first and second lead members 151 and 152 may be implemented to be similar to those shown in FIG. 1 in terms of the one ends connected to the first and second substrates 110 and 120 in direction of the stacking of these substrates and other ends exposed to the outside, but different from to those shown in FIG. 1 in terms of being aligned on opposite sides with respect to the semiconductor chip 130.

With reference to FIG. 4B, the first and second lead members 151 and 152 may be implemented to be similar to those shown in FIG. 1 in terms of being aligned on one side with respect to the semiconductor chip 130, but different from those shown in FIG. 1 in terms of having a bent shape between the one end and the other end other than straight shape.

With reference to FIG. 4C, the first and second lead members 151 and 152 may be implemented to be similar to those shown in FIG. 4A in terms of being aligned on the opposite side with respect to the semiconductor chip 130 and those shown in FIG. 4B in terms of having a bent shape between the one end and the other end.

In addition, as long as it is possible to be electrically connected at one end to an internal component of the power module 100 and exposed at the other end to the outside, the first and second lead members 151 and 152 of the power module 100 with double-sided cooling may be implemented in various shapes and structures.

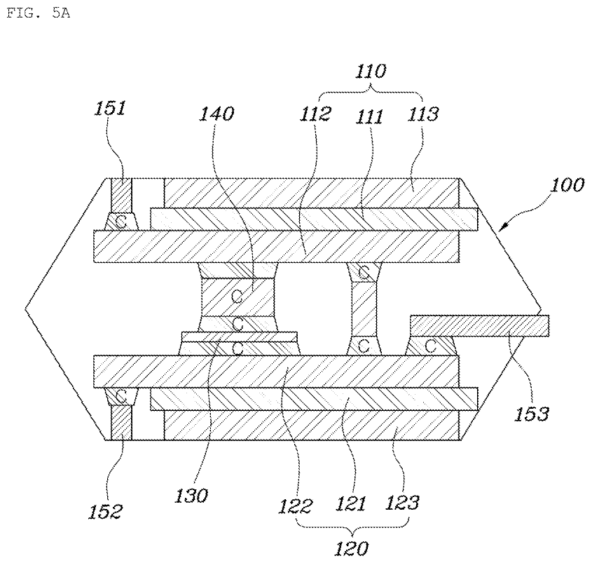

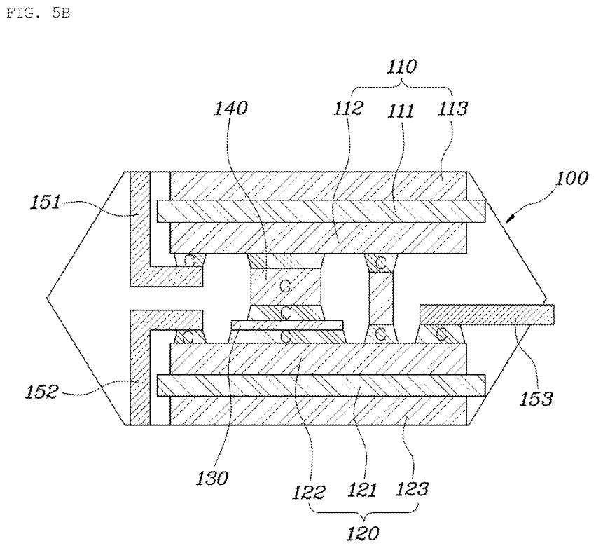

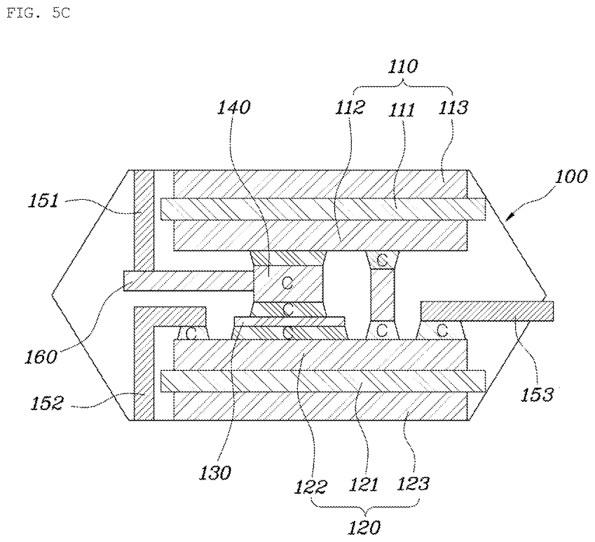

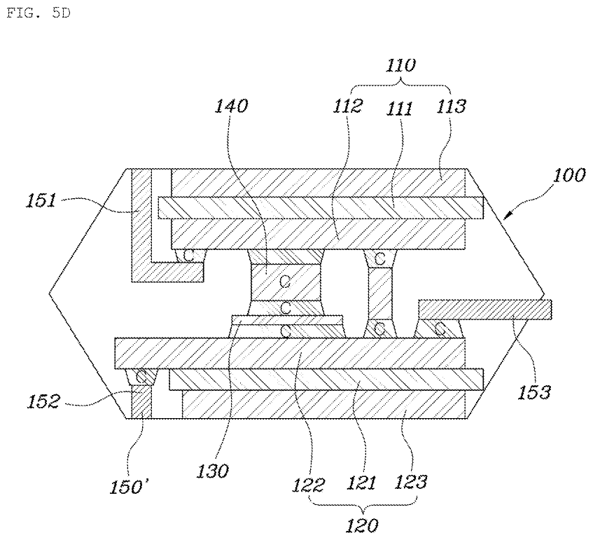

In some implementations, FIGS. 5A to 5D shows the power module 100 including a third lead member 153 in addition to the first and second lead members 151 and 152.

In detail, the third lead member 153 extends in the direction of extension of the first substrate 110 or the second substrate 120 and is connected at one end to at least one of the first and second substrates 110 and 120 and exposed at the other end to the outside in the direction of extension.

That is, unlike the first and second lead members 151 and 152 of which one ends and the other ends are positioned at different levels in the vertical direction, the third lead member 153 may have the one end and the other end positioned at the same level in the vertical direction on the drawing.

In addition, the third lead member 153 may protrude in the direction of the extension to be exposed to the outside, and the external terminal 200 may be connected to the protruding part.

In this case, the first and third lead members 151 and 153 may be connected to different external terminals 200, and furthermore, when the second lead member 152 is provided, the first to third lead members 151, 152, and 153 can be connected to different external terminals. The third lead member 153 may also be aligned on the opposite side relative to the first lead member 151 with respect to the semiconductor chip 130 in the direction of extension.

For example, in FIGS. 5A to 5D, an external terminal 200 corresponding to the P terminal may be connected to the first lead member 151, an external terminal 200 corresponding to the N terminal may be connected to the second lead member 152, and an external terminal 200 corresponding to the O terminal may be connected to the third lead member 153.

In some examples, with reference to FIG. 5C, the first lead member 151 may be connected at one end to the first substrate 110 via an insertion member 160 connected to an internal component (e.g., spacer 140) instead of being directly connected to the first substrate 110. In this case, although the specific connection structure may vary, the first lead member 151 is still connected at one end to the first substrate 110 and is exposed at the other end to the outside. Obviously, the same structure may also be applied to the second lead member 152.

However, unlike the implementations shown in FIGS. 5A to 5D, the arrangement and placement of the first lead member 151, second lead member 152, and third lead member 153 may be changed considering convenience in connection with other components, ease of packaging, etc.

As described above, the power module in various implementations of the present disclosure is advantageous in terms of implementing a compact current loop through the lead structure allowing the external terminals connected to the power module to be arranged in a short vertical direction rather than a wide horizontal direction.

This allows for an enhancement in the performance of the power module by mitigating or shortening the extension of the current path even when component sizes are enlarged for high power and heat dissipation purposes.

Although the present disclosure has been illustrated and described in connection with specific implementations, it will be obvious to those skilled in the art that various modification and changes can be made thereto without departing from the scope of the present disclosure that is defined by the appended claims.

What is claimed is:

1. A power module comprising:
a first substrate, the first substrate comprising a plurality of layers that are stacked in a first direction and extend in a second direction crossing the first direction;
a semiconductor chip connected to the first substrate in the first direction; and
a first lead that extends in the first direction, the first lead having (i) a first end that is electrically connected to the first substrate and (ii) a second end that is exposed to an outside of the power module.

2. The power module of claim 1, wherein the second end of the first lead is connected to an external terminal disposed outside of the power module.

3. The power module of claim 1, further comprising:
a molding that covers at least a part of each of the first substrate, the semiconductor chip, and the first lead,
wherein the second end of the first lead defines an exposed surface that is exposed outside of the molding.

4. The power module of claim 1, wherein the second end of the first lead extends to a position corresponding to an outer surface of an outermost layer among the plurality of layers of the first substrate in the first direction.

5. The power module of claim 1, wherein the first lead extends in the second direction from the first end connected to the first substrate, is curved in the second direction, and extends in the first direction to the second end exposed to the outside.

6. The power module of claim 1, wherein the plurality of layers comprise:
an insulating layer having a surface that faces the semiconductor chip; and
a metal layer arranged on the surface of the insulating layer that faces the semiconductor chip, and
wherein the first end of the first lead is connected to the metal layer.

7. The power module of claim 1, further comprising:
a second substrate spaced apart from the first substrate in the first direction, wherein the semiconductor chip is positioned between the first substrate and the second substrate; and
a second lead that extends in the first direction, the second lead having (i) a first end electrically connected to the second substrate and (ii) a second end exposed to the outside.

8. The power module of claim 7, wherein the second end of the first lead and the second end of the second lead are connected to different external terminals, respectively.

9. The power module of claim 8, wherein the different external terminals are a P terminal and an N terminal, respectively.

10. The power module of claim 7, wherein the second end of the first lead and the second end of the second lead are disposed at one side relative to the semiconductor chip in the second direction.

11. The power module of claim 10, wherein the second end of the first lead and the second end of the second lead at least partially overlap each other along the first direction.

12. The power module of claim 7, further comprising:
a third lead that extends in the second direction, the third lead having (i) a first end connected to at least one of the first substrate or the second substrate and (ii) a second end exposed to the outside.

13. The power module of claim 12, wherein the second end of the third lead protrudes to the outside in the second direction.

14. The power module of claim 12, wherein the first lead and the third lead are connected to different external terminals, respectively.

15. The power module of claim 12, wherein the first lead and the third lead are disposed at opposite sides with respect to the semiconductor chip in the second direction.
